(19) United States
(12) Patent Application Publication
(10) Pub. No.: US 2026/0231736 A1
(43) Pub. Date: Aug. 6, 2026

(54) SEMICONDUCTOR DEVICE

(71) Applicant: Samsung Electronics Co., Ltd., Suwon-si (KR)

(72) Inventors: SUHAENG HEO, Suwon-si (KR); JINKYU KIM, Suwon-si (KR); INHYUN SONG, Suwon-si (KR); SEOKJUN WON, Suwon-si (KR); WANGKYU LIM, Suwon-si (KR); Sumi JANG, Suwon-si (KR); Myungjin CHUNG, Suwon-si (KR)

(21) Appl. No.: 19/298,404

(22) Filed: Aug. 13, 2025

(30) Foreign Application Priority Data
Feb. 3, 2025 (KR) 10-2025-0013078

(51) Int. Cl. H01L 21/66; H01L 23/528; H10D 84/83

(52) U.S. Cl. CPC H10P 74/273; H10D 84/832; H10P 74/203; H10W 20/427

(57) ABSTRACT

Provided is a semiconductor device including a first source/drain pattern and a second source/drain pattern, a first power line disposed at a lower level than each of the first source/drain pattern and the second source/drain pattern, and the first power line being electrically connected to the first source/drain pattern, an upper active contact on the second source/drain pattern, a channel structure connected to at least one of the first source drain pattern or the second source/drain pattern, and a first pad electrically connected to the first source/drain pattern through the first power line.

### CROSS-REFERENCE TO RELATED APPLICATIONS

This U.S. non-provisional patent application claims priority under 35 U.S.C. § 119 of Korean Patent Application No. 10-2025-0013078, filed on Feb. 3, 2025, the entire contents of which are hereby incorporated by reference.

### BACKGROUND

The present disclosure herein relates to a semiconductor device, and more particularly, to a semiconductor device including pads.

A semiconductor device includes an integrated circuit composed of metal-oxide-semiconductor field effect transistors (MOSFETs). Semiconductor devices are gradually decreasing in size. Scaling down of the metal-oxide-semiconductor field effect transistors is also gradually being accelerated. As the metal-oxide-semiconductor field effect transistors are gradually scaled down, operation characteristics of semiconductor devices may deteriorate. Accordingly, research on various methods for addressing limitations caused by high-integration of semiconductor devices and forming semiconductor devices with more excellent performance are being conducted.

### SUMMARY

The present disclosure provides a semiconductor device with improved electrical characteristics and reliability and a method for manufacturing the same.

An embodiment of the inventive concept provides a semiconductor device including a first source/drain pattern and a second source/drain pattern, a first power line disposed at a lower level than each of the first source/drain pattern and the second source/drain pattern, the first power line being electrically connected to the first source/drain pattern, an upper active contact on the second source/drain pattern, a channel structure connected to at least one of the first source/drain pattern or the second source/drain pattern, and a first pad electrically connected to the first source/drain pattern through the first power line, wherein an upper level of an upper surface of the first pad is vertically higher than an upper level of an upper surface of the upper active contact, and a lower level of a lower surface of the first pad is vertically lower than a lowermost level of the first source/drain pattern and the second source/drain patterns.

In an embodiment of the inventive concept, a semiconductor device includes a source/drain pattern, power lines disposed at a lower vertical level than the source/drain pattern, an upper active contact on the source/drain pattern, a channel structure connected to the source/drain pattern, and pads electrically connected to the power lines, wherein the power lines extend in a first direction, the power lines are spaced apart from each other in a second direction, and the pads include a first pad and a second pad spaced apart from each other in the first direction with the power lines therebetween, and a third pad and a fourth pad spaced apart from each other in a second direction intersecting the first direction with the power lines therebetween.

In an embodiment of the inventive concept, a semiconductor device includes a first source/drain pattern and a second source/drain pattern, semiconductor patterns connected to at least one of the first source/drain pattern or the second source/drain pattern, a gate electrode overlapping the semiconductor patterns, a power line disposed at a lower vertical level than the first source/drain pattern and the second source/drain pattern, an upper active contact on the second source/drain pattern, a bump disposed at a lower vertical level than the power line, and electrically connected to the power line, a lower active contact connecting the power line and the first source/drain pattern, an upper via on the upper active contact, an upper line on the upper via, and a pad electrically connected to the first source/drain pattern through the power line and the upper active contact, wherein a distance between an upper surface of the pad and a lower surface of the pad is greater than a distance between an upper surface of the upper line and an upper surface of the power line.

In an embodiment of the inventive concept, a method for manufacturing a semiconductor device includes forming a fin pattern, forming an element separation layer on a sidewall of the fin pattern, forming a source/drain pattern on the fin pattern, forming an interlayered insulating layer on a source/drain pattern, forming a lower active contact connected to the source/drain pattern, forming a power line connected to the lower active contact, forming a pad electrically connected to the power line, disposing the pad, the power line and the source/drain pattern between a probe pin and a measurement portion, applying a voltage to the pad through the probe pin, and measuring a hot electron with the measurement portion, wherein the pad penetrates the interlayered insulating layer and the element separation layer.

In an embodiment, the method for manufacturing a semiconductor device may further include forming a bump electrically connected to the power line.

In an embodiment, the method for manufacturing a semiconductor device may include forming a bump electrically connected to the power line, and removing the bump, wherein the forming of the bump and the removing of the bump are performed before the pad, the power line and the source/drain pattern are disposed between the probe pin and the measurement portion.

In an embodiment, the method for manufacturing a semiconductor device may include forming an upper active contact penetrating the interlayered insulating layer, forming upper lines electrically connected to the upper active contact, and removing at least some of the upper lines, wherein the removing of the at least some of the upper lines is performed before the pad is formed.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a plan view of a semiconductor device according to some embodiments;

FIG. 1B is an enlarged diagram of region Q1 of FIG. 1A;

FIG. 1C is an enlarged diagram of region Q2 of FIG. 1A;

FIG. 1D is a cross-sectional view taken along line A-A′ of FIG. 1B;

FIG. 1E is a cross-sectional view taken along line B-B′ of FIG. 1C;

FIGS. 2A and 2B are cross-sectional views showing a method for manufacturing a semiconductor device according to FIGS. 1A to 1E;

FIGS. 3A, 3B, 3C and 3D are cross-sectional views showing a method for testing a semiconductor device according to some embodiments;

FIG. 4 is a cross-sectional view of a semiconductor device according to some embodiments; and

FIG. 5 is a cross-sectional view of a semiconductor device according to some embodiments.

### DETAILED DESCRIPTION

Throughout the specification, when a component is described as “comprising” or “including” a particular element or group of elements, it is to be understood that the component is formed of only the element or the group of elements, or the element or group of elements may be combined with additional elements to form the component, unless the context indicates otherwise.

Items described in the singular herein may be provided in plural, as can be seen, for example, in the drawings. Thus, the description of a single item that is provided in plural should be understood to be applicable to the remaining plurality of items unless context indicates otherwise.

Terms such as the “same,” or “equal” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes.

It will be understood that when an element is referred to as being “connected” to “on” another element, it can be directly connected or coupled to or on the other element or intervening elements may be present. In contrast, when an element is referred to as “in contact with” another element (or using any form of the word “contact”), there are no intervening elements present at the point of contact. As used herein the terms “over”, “cover” or “covering” are intended to mean that an element is over another element. The elements may be touching or not. An element “over” or “covering” another element need not cover an entire element to be considered “covering”. The terms are intended to encompass one element “over” or “covering” all, or any part of, an element below it.

Spatially relative terms, such as “below,” “lower,” “upper,” and the like, may be used herein for ease of description to describe positional relationships, such as illustrated in the figures, for example. It will be understood that the spatially relative terms encompass different orientations of the device in addition to the orientation depicted in the figures.

As used herein, items described as being “electrically connected” are configured such that an electrical signal can be passed from one item to the other. A passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

A “semiconductor device” may be a semiconductor chip (i.e., a semiconductor device singulated from (e.g., cut from) a wafer).

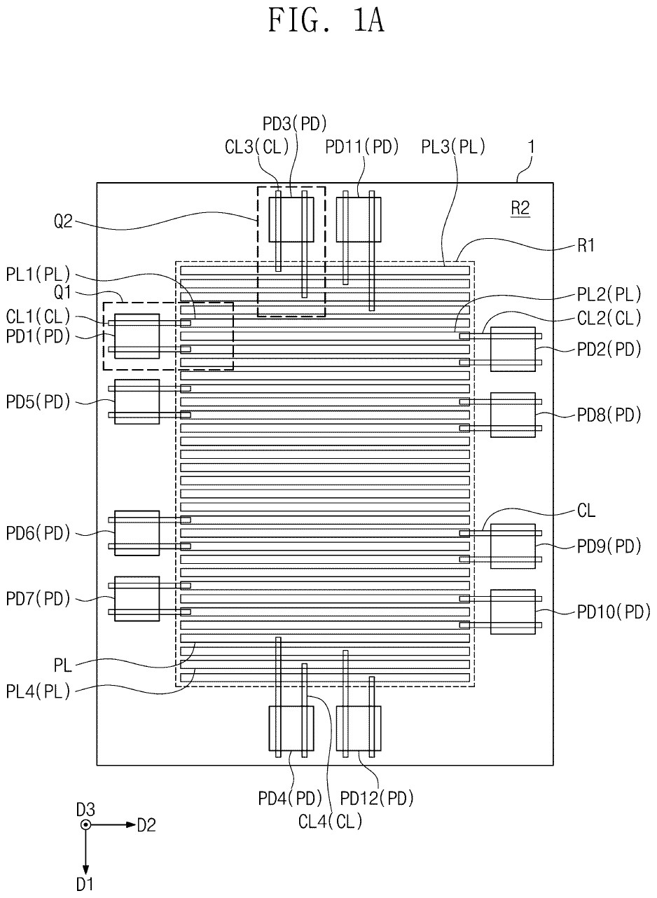

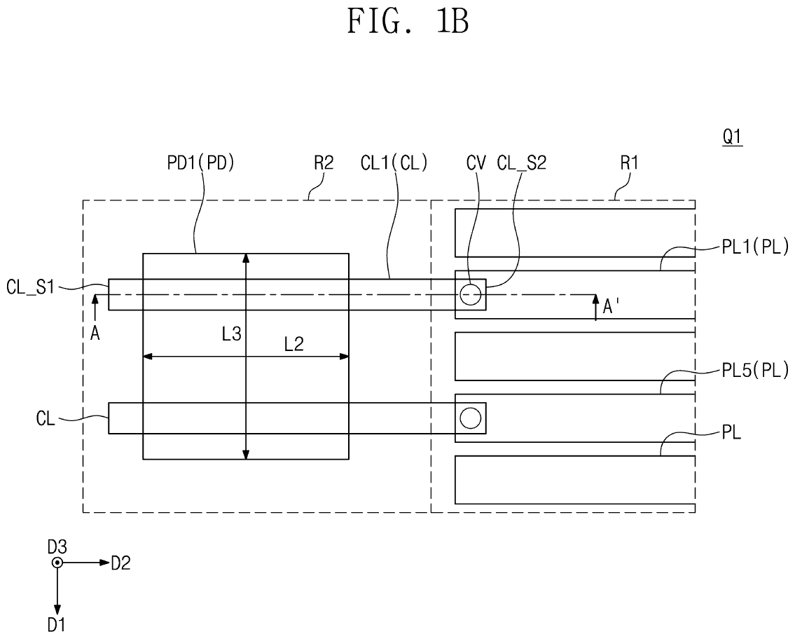

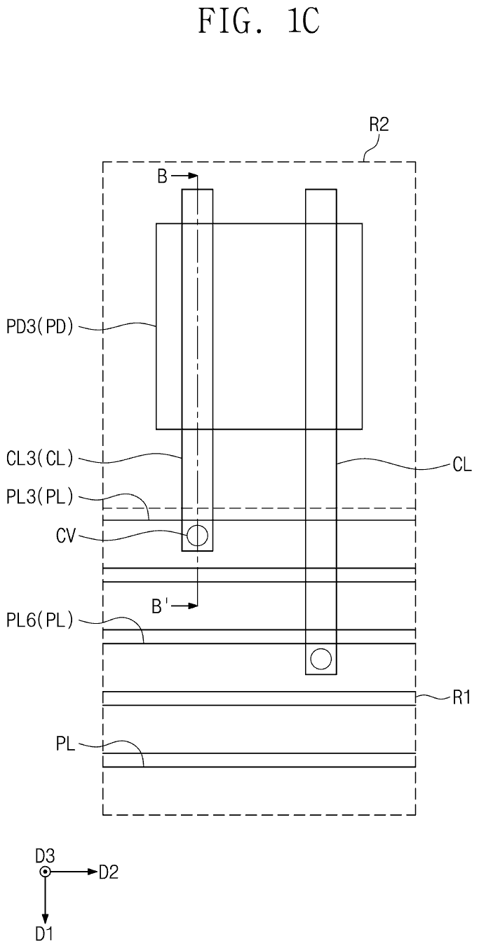

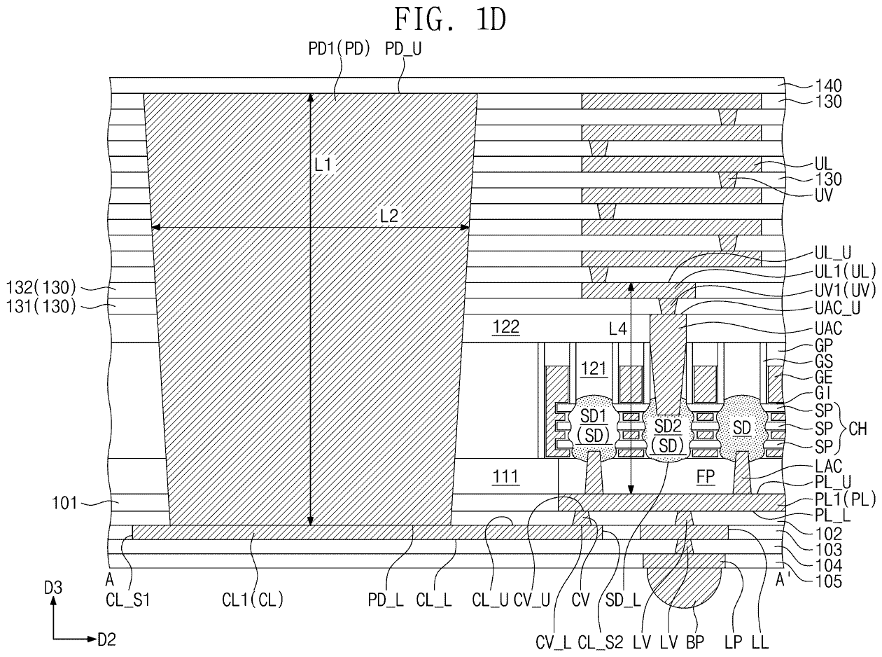

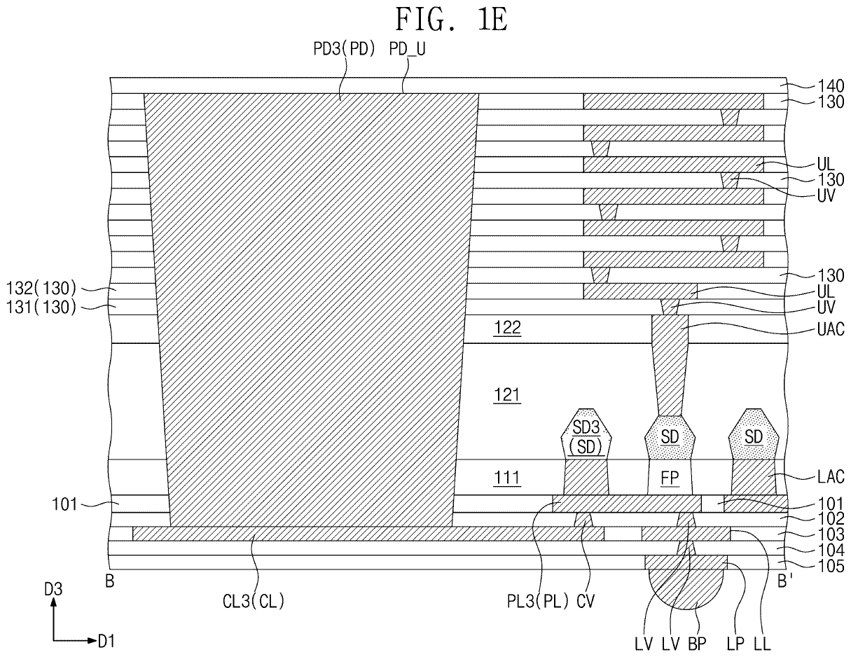

FIG. 1A is a plan view of a semiconductor device according to some embodiments. FIG. 1B is an enlarged diagram of region Q1 of FIG. 1A. FIG. 1C is an enlarged diagram of region Q2 of FIG. 1A. FIG. 1D is a cross-sectional view taken along line A-A′ of FIG. 1B. FIG. 1E is a cross-sectional view taken along line B-B′ of FIG. 1C.

Referring to FIG. 1A, the semiconductor device may include a first region R1 and a second region R2. The second region R2 may surround the first region R1. The first region R1 and the second region R2 may be distinguished on a view of a plane defined by a first direction D1 and a second direction D2. The first direction D1 and the second direction D2 may cross each other. For example, the first direction D1 and the second direction D2 may be horizontal directions perpendicular to each other.

The semiconductor device may include power lines PL. The power lines PL may be disposed in the first region R1. The power lines PL may extend in the second direction D2. The power lines PL may be arranged in the first direction D1. A power voltage VDD or a ground voltage VSS may be provided to the power lines PL. The power lines PL may include or be a conductive material.

The semiconductor device may include pads PD. The pads PD may be disposed in the second region R2. The pads PD may surround the first region R1. The pads PD may surround the power lines PL. The pads PD may be electrically connected to the power lines PL. The pads PD may include or be a conductive material. For example, the pads PD may include or be tungsten.

The various pads of a device described herein may be conductive terminals connected to internal wiring of the device, and may transmit signals and/or supply voltages between an internal wiring and/or internal circuit of the device and an external source. The various pads may be provided on or near an external surface of the device and may have a planar surface having dimensions greater than wiring (e.g., X-Y horizontal dimensions of a pad are both greater than the width of an internal wiring to which it is connected) to promote an electrical connection to a further terminal, such as a bump or solder ball, and/or an external wiring.

The semiconductor device may include connection lines CL. The connection lines CL may extend from the second region R2 to the first region R1. The connection line CL may electrically connect the pad PD and the power line PL. The connection lines CL may include or be a conductive material.

The pads PD may include a first pad PD1, a second pad PD2, a third pad PD3, a fourth pad PD4, a fifth pad PD5, a sixth pad PD6, a seventh pad PD7, an eighth pad PD8, a ninth pad PD9, a tenth pad PD10, an eleventh pad PD11 and a twelfth pad PD12.

The first pad PD1 and the second pad PD2 may be spaced apart from each other in the second direction D2 with the power lines PL therebetween. The power lines PL and the first region R1 may be disposed between the first pad PD1 and the second pad PD2.

The third pad PD3 and the fourth pad PD4 may be spaced apart from each other in the first direction D1 with the power lines PL therebetween. The power lines PL and the first region R1 may be disposed between the third pad PD3 and the fourth pad PD4.

The power lines PL may include a first power line PL1 electrically connected to the first pad PD1, a second power line PL2 electrically connected to the second pad PD2, a third power line PL3 electrically connected to the third pad PD3, and a fourth power line PL4 electrically connected to the fourth pad PD4.

The ground voltage may be provided to the first power line PL1. The power voltage may be provided to the second power line PL2. The ground voltage may be provided to the third power line PL3. The power voltage may be provided to the fourth power line PL4.

Each of the first, third, sixth, eighth, tenth and twelfth pads PD1, PD3, PD6, PD8, PD10 and PD12 may be electrically connected to a corresponding power line PL to which the ground voltage is provided. Each of the second, fourth, fifth, seventh, ninth and eleventh pads PD2, PD4, PD5, PD7, PD9 and PD11 may be electrically connected to a corresponding power line PL to which the power voltage is provided.

The power lines PL to which the ground voltage is provided may be electrically connected to each other. The power voltage may include a first power voltage VDD_0, a second power voltage VDD_1, a third power voltage VDD_2, a fourth power voltage VDD_3, a fifth power voltage VDD_4 and a sixth power voltage VDD_5. Power lines PL to which the first power voltage is provided may be electrically separated from power lines PL to which a power voltage different from the first power voltage is provided. For example, the power line PL to which the first power voltage is provided may be electrically separated from the power line PL to which the second power voltage is provided.

According to some embodiments, the seventh pad PD7 may be electrically connected to the power line PL to which the first power voltage is provided, the fifth pad PD5 may be electrically connected to the power line PL to which the second power voltage is provided, the fourth pad PD4 may be electrically connected to the power line PL to which the third power voltage is provided, the eleventh pad PD11 may be electrically connected to the power line PL to which the fourth power voltage is provided, the second pad PD2 may be electrically connected to the power line PL to which the fifth power voltage is provided, and the ninth pad PD9 may be electrically connected to the power line PL to which the sixth power voltage is provided. In this example, the second power line PL2 may be electrically separated from the fourth power line PL4.

The connection lines CL may include a first connection line CL1 electrically connecting the first pad PD1 and the first power line PL1, a second connection line CL2 electrically connecting the second pad PD2 and the second power line PL2, a third connection line CL3 electrically connecting the third pad PD3 and the third power line PL3, and a fourth connection line CL4 electrically connecting the fourth pad PD4 and the fourth power line PL4.

The first and second connection lines CL1 and CL2 may extend in the second direction D2. The third and fourth connection lines CL3 and CL4 may extend in the first direction D1.

Referring to FIGS. 1B, 1C, 1D and 1E, the semiconductor device may include a first lower insulating layer 101, a second lower insulating layer 102, a third lower insulating layer 103, a fourth lower insulating layer 104 and a fifth lower insulating layer 105. The fourth lower insulating layer 104 may be provided on the fifth lower insulating layer 105. The third lower insulating layer 103 may be provided on the fourth lower insulating layer 104. The second lower insulating layer 102 may be provided on the third lower insulating layer 103. The first lower insulating layer 101 may be provided on the second lower insulating layer 102. The lower insulating layers 101, 102, 103, 104 and 105 may include or be an insulating material. According to some embodiments, each of the lower insulating layers 101, 102, 103, 104 and 105 may be a multiple layer including a plurality of insulating layers.

A lower pad LP may be disposed in the fifth lower insulating layer 105. The lower pad LP may be disposed at a lower vertical level than the power line PL. The lower pad LP may include or be a conductive material. A bump BP in contact with the lower pad LP may be provided. The bump BP may be disposed at a lower vertical level than the power line PL. The bump BP may include or be a conductive material.

Lower vias LV may be provided in the fourth lower insulating layer 104. Connection lines CL and lower lines LL may be provided in the third lower insulating layer 103. The lower vias LV and connection vias CV may be provided in the second lower insulating layer 102. The power lines PL may be provided in the first lower insulating layer 101.

The lower via LV, the lower line LL and the lower pad LP may electrically connect the power line PL and the bump BP. The connection via CV and the connection line CL may electrically connect the power line PL and the pad PD.

The lower vias LV, the lower lines LL and the connection vias CV may include or be a conductive material.

Fin patterns FP may be provided on the power lines PL. According to some embodiments, the fin patterns FP may be provided on the first lower insulating layer 101. The fin patterns FP may extend in the second direction D2. The fin patterns FP may be arranged spaced apart from each other in the first direction D1. The fin patterns FP may include or be an insulating material. For example, the fin patterns FP may include or be nitride.

According to some embodiments, the fin patterns FP may include or be a semiconductor material. For example, the semiconductor material may be silicon. According to some embodiments, a semiconductor substrate may be provided on the first lower insulating layer 101, and the fin patterns FP may be parts, protruding in a third direction D3, of the semiconductor substrate. In this example, the fin patterns FP may be connected to each other by a lower portion of the semiconductor substrate. The third direction D3 may cross the first direction D1 and the second direction D2. For example, the third direction D3 may be a vertical direction perpendicular to the first direction D1 and the second direction D2.

An element separation layer 111 may be provided. The element separation layer 111 may surround the fin patterns FP. The fin patterns FP may be spaced apart from each other by the element separation layer 111. The element separation layer 111 may be provided on a sidewall of the fin pattern FP. The element separation layer 111 may be in contact with the sidewall of the fin pattern FP. The element separation layer 111 may include or be an insulating material. For example, the element separation layer 111 may include or be oxide. According to some embodiments, the element separation layer 111 may be a multiple layer including a plurality of insulating layers.

A lower active contact LAC may be provided. The lower active contact LAC may be provided on the power line PL. The lower active contact LAC may be electrically connected to the power line PL. A lower surface of the lower active contact LAC may be in contact with an upper surface PL_U of the power line PL. The lower active contact LAC may penetrate the fin pattern FP in the third direction D3. The lower active contact LAC may include or be a conductive material.

A source/drain pattern SD may be provided on the fin pattern FP. The source/drain pattern SD may be epitaxial patterns formed in a selective epitaxial growth (SEG) process. The source/drain pattern SD may include or be a semiconductor material. The source/drain pattern SD may include or be at least one of silicon (Si), germanium (Ge) or silicon-germanium (SiGe). The source/drain pattern SD may be doped with an impurity.

A channel structure CH connected to the source/drain pattern SD may be provided. The channel structure CH may be provided between the source/drain patterns SD adjacent to each other in the second direction D2. The channel structure CH may include semiconductor patterns SP overlapping each other in the third direction D3. The semiconductor patterns SP may be connected to the source/drain pattern SD. For example, the semiconductor patterns SP may include or be at least one of silicon, germanium or silicon-germanium.

A gate electrode GE crossing the fin pattern FP may be provided. The gate electrode GE may overlap the fin pattern FP in the third direction D3. The gate electrode GE may extend in the first direction D1. The gate electrode GE may overlap the semiconductor patterns SP in the third direction D3. The gate electrode GE and the semiconductor patterns SP may constitute a three-dimensional field effect transistor (for example, an MBCFET or a GAAFET).

A gate insulating layer GI in contact with the gate electrode GE may be provided. The gate electrode GE and the semiconductor pattern SP may be spaced apart from each other by the gate insulating layer GI. The gate electrode GE and the source/drain pattern SD may be spaced apart from each other by the gate insulating layer GI. The gate insulating layer GI may include or be an insulating material. For example, the gate insulating layer GI may include or be oxide.

A pair of gate spacers GS may be disposed on both sides of the gate electrode GE. In non-limiting examples, a pair of gate spacers GS may be on opposite sides from each other of each gate electrode GE in the second direction D2. The gate spacers GS may extend in the first direction D1. The gate spacers GS may include or be an insulating material.

Gate capping patterns GP may be provided on the gate electrodes GE. For example a gate capping pattern GP may be provided on a corresponding gate electrode GE. The gate capping pattern GP may extend in the first direction D1. The gate capping pattern GP may include or be an insulating material.

A first interlayered insulating layer 121 may be provided. The first interlayered insulating layer 121 may be provided on the source/drain pattern SD and the gate spacer GS. A second interlayered insulating layer 122 may be provided on the first interlayered insulating layer 121. The second interlayered insulating layer 122 may be provided on the first interlayered insulating layer 121, the gate spacers GS and the gate capping patterns GP. The first and second interlayered insulating layers 121 and 122 may include or be an insulating material. For example, the first and second interlayered insulating layers 121 and 122 may include or be oxide.

Upper active contacts UAC may be provided. The upper active contact UAC may penetrate the first and second interlayered insulating layers 121 and 122. The upper active contacts UAC may include or be a conductive material.

Upper insulating layers 130 may be provided on the second interlayered insulating layer 122. The upper insulating layers 130 may be stacked on the second interlayered insulating layer 122 in the third direction D3. The upper insulating layers 130 may include a first upper insulating layer 131 on the second interlayered insulating layer 122 and a second upper insulating layer 132 on the first upper insulating layer 131. The upper insulating layers 130 may include or be an insulating material.

Upper vias UV and upper lines UL may be provided in the upper insulating layers 130. The upper vias UV and the upper lines UL may be electrically connected to the upper active contact UAC. At least one of the upper lines UL may be a signal line. The upper vias UV and the upper lines UL may include or be a conductive material.

The pad PD may penetrate the upper insulating layers 130, the second interlayered insulating layer 122, the first interlayered insulating layer 121, the element separation layer 111, the first lower insulating layer 101, and the second lower insulating layer 102 in the third direction D3. The pad PD may be surrounded by the upper insulating layers 130, the second interlayered insulating layer 122, the first interlayered insulating layer 121, the element separation layer 111, the first lower insulating layer 101 and the second lower insulating layer 102.

A cover insulating layer 140 may be provided on the pad PD and an uppermost upper insulating layer 130 among the upper insulating layers 130. All of an upper surface PD_U of the pad PD may be in contact with a lower surface of the cover insulating layer 140. In example embodiments, a lower surface of the cover insulating layer 140 is over at least a portion of an upper surface PD_U of the pad PD. The cover insulating layer 140 may include or be an insulating material. For example, the cover insulating layer 140 may include or be oxide.

According to some embodiments, the cover insulating layer 140 may be a multiple layer including a plurality of insulating layers. According to some embodiments, some of the upper lines UL and some of the upper vias UV may be provided in the cover insulating layer 140. According to some embodiments, the cover insulating layer 140 may be a molding layer covering a semiconductor chip. In example embodiments, the molding layer may include or be a polymer material.

Referring to FIG. 1B, the power lines PL may further include or be a fifth power line PL5 spaced apart from the first power line PL1 in the first direction D1. The fifth power line PL5 may be electrically connected to the first pad PD1 through the connection line CL. The ground voltage may be applied to the fifth power line PL5.

The first connection line CL1 may include a first sidewall CL_S1 and a second sidewall CL_S2 opposed to the first sidewall CL_S1. The first sidewall CL_S1 and the second sidewall CL_S2 may be spaced apart from each other in the second direction D2. The first pad PD1 may be disposed between the first sidewall CL_S1 and the second sidewall CL_S2 of the first connection line CL1. The second sidewall CL_S2 of the first connection line CL1 may overlap the first power line PL1 in the third direction D3. A distance in the second direction D2 between the first sidewall CL_S1 and the second sidewall CL_S2 of the first connection line CL1 may be greater than a width L2 in the second direction D2 of the first pad PD1.

Referring to FIG. 1C, the power lines PL may further include a sixth power line PL6 spaced apart from the third power line PL3 in the first direction D1. The sixth power line PL6 may be electrically connected to the third pad PD3 through the connection line CL. The ground voltage may be applied to the sixth power line PL6.

Referring to FIG. 1D, when levels of the connection via CV and the lower via LV become lower, a width in the second direction D2 of the connection via CV and the lower via LV may become greater. When a level of the upper via UV becomes lower, a width in the second direction D2 of the upper via UV may become smaller.

The source/drain patterns SD may include a first source/drain pattern SD1 electrically connected to the first power line PL1 and a second source/drain pattern SD2 electrically connected to the upper active contact UAC. The upper active contact UAC may be provided on the second source/drain pattern SD2.

The first power line PL1 may be disposed at a lower vertical level than the first and second source/drain patterns SD1 and SD2. The first power line PL1 may be electrically connected to the first source/drain pattern SD1 through the lower active contact LAC. The lower active contact LAC may be connected to the first source/drain pattern SD1 and the first power line PL1. The lower active contact LAC may be in contact with the first source/drain pattern SD1 and the first power line PL1.

The first pad PD1 may be electrically connected to the first source/drain pattern SD1 through the first connection line CL1, the connection via CV, the first power line PL1 and the lower active contact LAC.

A level of the upper surface PD_U of the first pad PD1 may be higher than a level of an upper surface UAC_U of the upper active contact UAC. A level of a lower surface PD_L of the first pad PD1 may be lower than levels of lowermost portions SD_L of the first and second source/drain patterns SD1 and SD2.

A lower surface CV_L of the connection via CV connecting the first power line PL1 and the first connection line CL1 may be in contact with an upper surface CL_U of the first connection line CL1. An upper surface CV_U of the connection via CV connecting the first power line PL1 and the first connection line CL1 may be in contact with a lower surface PL_L of the first power line PL1.

The lower surface PD_L of the first pad PD1 may be in contact with the upper surface CL_U of the first connection line CL1. A level of the lower surface PD_L of the first pad PD1 may be lower than a level of a lower surface PL1_L of the first power line PL1.

A distance L1 in the third direction D3 between the upper surface PD_U and the lower surface PD_L of the first pad PD1 may be greater than each of the width L2 in the second direction D2 of the first pad PD1 and a width L3 (see FIG. 1B) in the first direction D1 of the first pad PD1. When a level of the first pad PD1 becomes lower, the width L2 in the second direction D2 of the first pad PD1 and the width L3 in the first direction D1 of the first pad PD1 may become smaller. For example, the distance L1 in the third direction D3 between the upper surface PD_U and the lower surface PD_L of the first pad PD1 may be 70 μm to 100 μm, or 75 μm to 95 μm, or 80 μm to 90 μm. For example, the width in the second direction D2 of the upper surface PD_U of the first pad PD1 and the width in the first direction D1 of the upper surface PD_U of the first pad PD1 may be about 10 μm, or 9 μm to 11 μm, or 8 μm to 12 μm.

The upper vias UV may include a first upper via UV1 on the upper active contact UAC in contact with the second source/drain pattern SD2. The upper lines UL may include a first upper line UL1 on the first upper via UV1.

The distance L1 in the third direction D3 between the upper surface PD_U and the lower surface PD_L of the first pad PD1 may be greater than a distance L4 in the third direction D3 between an upper surface UL_U of the first upper line UL1 and the upper surface PL_U of the first power line PL1.

For example, a distance in the second direction D2 between the first sidewall CL_S1 of the first connection line CL1 and the first power line PL1 may be about 20 μm or 19 μm to 21 μm, or 18 μm to 22 μm.

Referring to FIG. 1E, the source/drain patterns SD may include a third source/drain pattern SD3 electrically connected to the third power line PL3.

The third power line PL3 may be disposed at a lower vertical level than the third source/drain pattern SD3. The third power line PL3 may be electrically connected to the third source/drain pattern SD3 through the lower active contact LAC. The lower active contact LAC may be in contact with the third source/drain pattern SD3 and the third power line PL3.

The third pad PD3 may be electrically connected to the third source/drain pattern SD3 through the third connection line CL3, the connection via CV, the third power line PL3 and the lower active contact LAC.

The semiconductor device according to some embodiments may include the pad PD electrically connected to the power line PL disposed at a lower vertical level than the source/drain patterns SD. Accordingly, a voltage may be applied to the power line PL disposed at the lower level than the source/drain patterns SD by using a probe pin in contact with the pad PD, and thus a hot electron generated by the voltage may be measured.

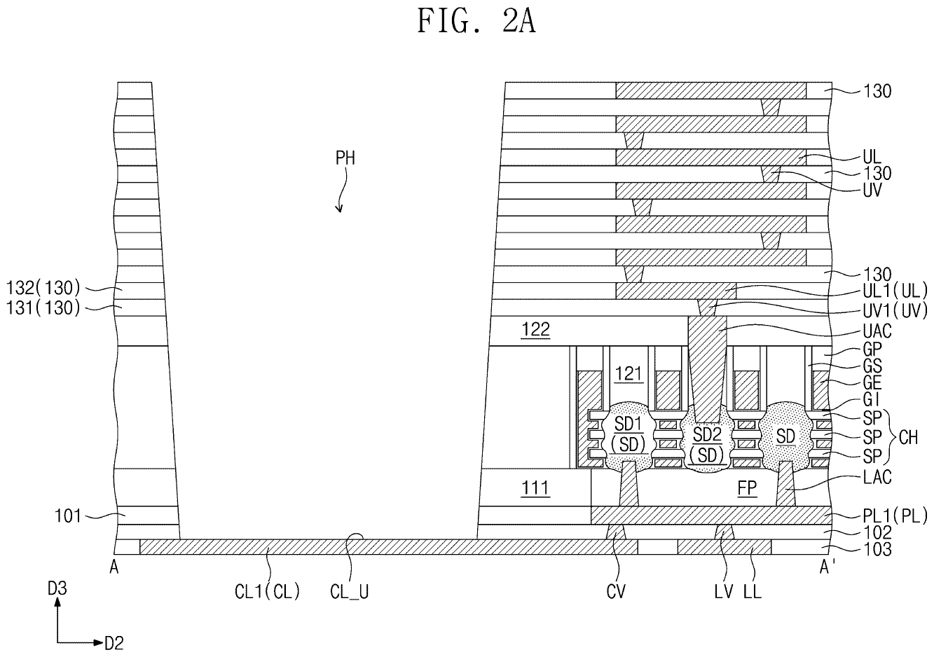

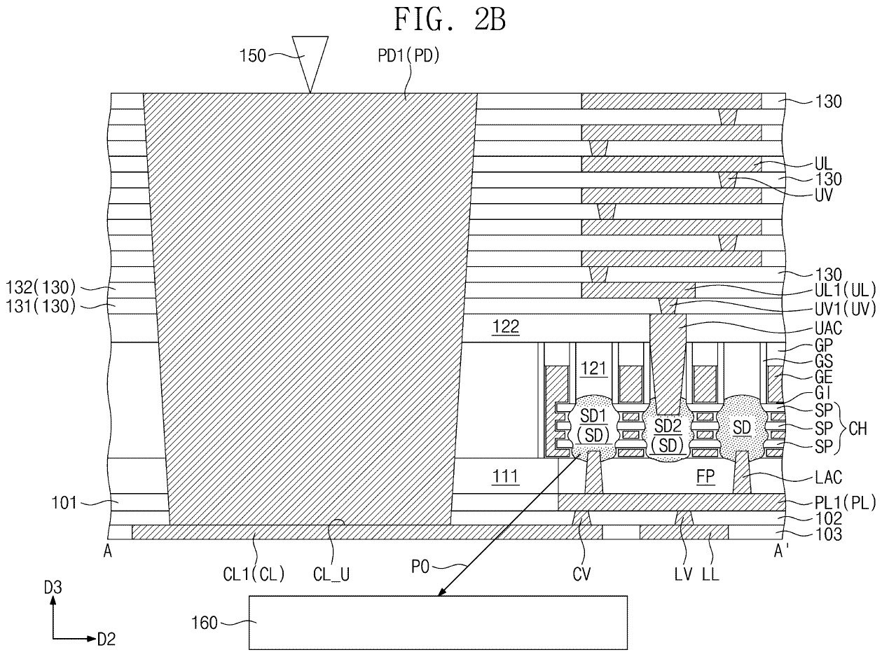

FIGS. 2A and 2B are cross-sectional views showing an example method for manufacturing a semiconductor device according to FIGS. 1A to 1E. FIGS. 2A and 2B may correspond to FIG. 1D. The example method for manufacturing a semiconductor device may include a method for testing a semiconductor device.

Referring to FIG. 2A, the fin patterns FP, the element separation layer 111, the channel structures CH, the source/drain patterns SD, the gate insulating layers GI, the gate electrodes GE, the gate capping patterns GP, the gate spacers GS, the first interlayered insulating layer 121, the second interlayered insulating layer 122 and the upper active contact UAC may be formed.

The upper insulating layers 130 may be formed on the second interlayered insulating layer 122. The upper vias UV and the upper lines UL may be formed in the upper insulating layers 130.

The lower active contacts LAC may be formed. The first lower insulating layer 101 and the power lines PL may be formed. The second lower insulating layer 102, the lower vias LV and the connection vias CV may be formed. The third lower insulating layer 103, the lower lines LL and the connection lines CL may be formed.

Penetration holes PH penetrating the upper insulating layers 130, the second interlayered insulating layer 122, the first interlayered insulating layer 121, the element separation layer 111, the first lower insulating layer 101 and the second lower insulating layer 102 in the third direction D3 may be formed. For example, the penetration holes PH may be formed in an ion milling process using an ion beam.

The upper surface CL_U of the connection line CL may be exposed by the penetration hole PH.

Referring to FIG. 2B, the pad PD may be formed in the penetration hole PH. Forming the pad PD may include depositing a conductive material (for example, tungsten) in the penetration hole PH.

The semiconductor device may be tested by using the pad PD. According to some embodiments, the semiconductor device may be tested by using hot electron analysis (HEA). According to some embodiments, a HEA apparatus may include a probe pin 150 and a measurement portion 160, and the semiconductor device may be disposed between the probe pin 150 and the measurement portion 160 in a process of testing the semiconductor device. The pads PD, the power lines PL, the source/drain patterns SD, the lower active contacts LAC, the upper active contacts UAC and the connection lines CL may be disposed between the probe pin 150 and the measurement portion 160.

The probe pin 150 may be brought into contact with an upper surface of the pad PD. A voltage may be applied to the pad PD through the probe pin 150. For example, a DC voltage may be applied to the pad PD through the probe pin 150. A hot electron may be generated in a defect of the semiconductor device by the voltage applied through the probe pin 150.

The measurement portion 160 may be disposed under the connection line CL. The measurement portion 160 may measure a photon PO generated by the hot electron. According to some embodiments, the measurement portion 160 may measure heat generated by the hot electron. According to some embodiments, the measurement portion 160 may measure the hot electron by using laser.

Whether or not there is a defect of the semiconductor device may be tested on the basis of the hot electron measured by the measurement portion 160.

The first region R1 (see FIG. 1A) of the semiconductor device may include a plurality of block regions. Each of the block regions may be electrically connected to a corresponding pad PD adjacent thereto. Whether or not there is a defect in the block region may be tested by using the pad PD adjacent to the block region. For example, whether or not there is a defect in the block region adjacent to the first pad PD1 may be tested by using the first pad PD1.

According to some embodiments, the pad PD may be formed on some of the connection lines CL, and may not be formed on others of the connection lines CL. In other words, some of the first to twelfth pads PD1 to PD12 may be omitted.

Referring to FIGS. 1A to 1E, the cover insulating layer 140 may be formed on the pads PD.

The fourth lower insulating layer 104 may be formed on the third lower insulating layer 103. The lower vias LV may be formed in the fourth lower insulating layer 104. The fifth lower insulating layer 105 may be formed on the fourth lower insulating layer 104. The lower pad LP may be formed in the fifth lower insulating layer 105. The bump BP may be formed on the lower pad LP.

In methods for manufacturing a semiconductor device according to some embodiments, before the fourth lower insulating layer 104, the fifth lower insulating layer 105, the lower via LV, the lower pad LP and the bump BP are formed, the semiconductor device may be tested by using the pad PD. Because the semiconductor device is tested in a state in which lower wires of the semiconductor device are minimized, a phenomenon that the photon PO is blocked by the lower wire may be prevented or limited. Accordingly, even when the probe pin 150 is disposed on the semiconductor device, and the measurement portion 160 is disposed under the semiconductor device, defect measurement accuracy of the semiconductor device may be improved.

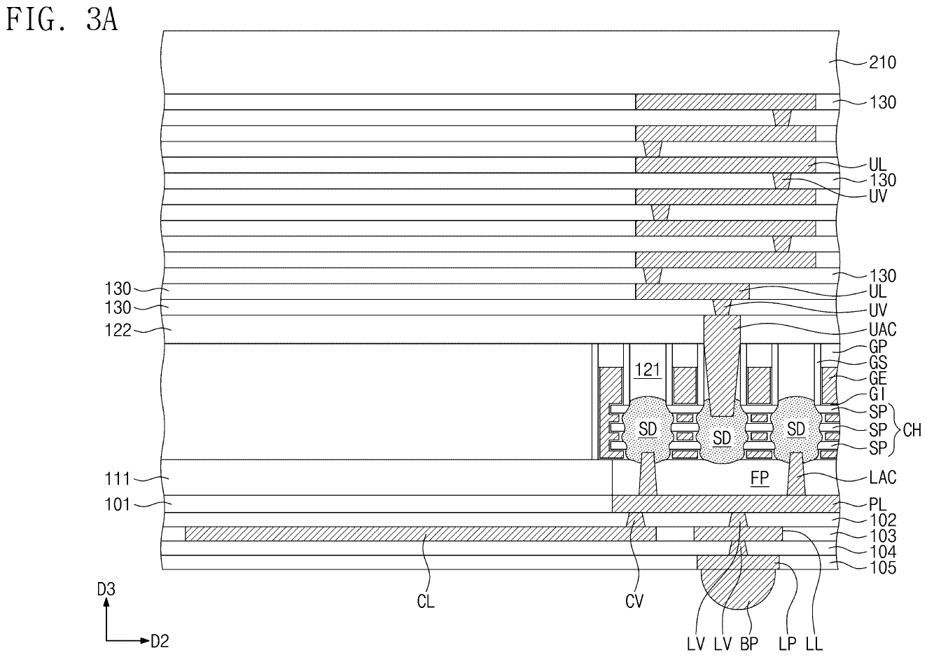

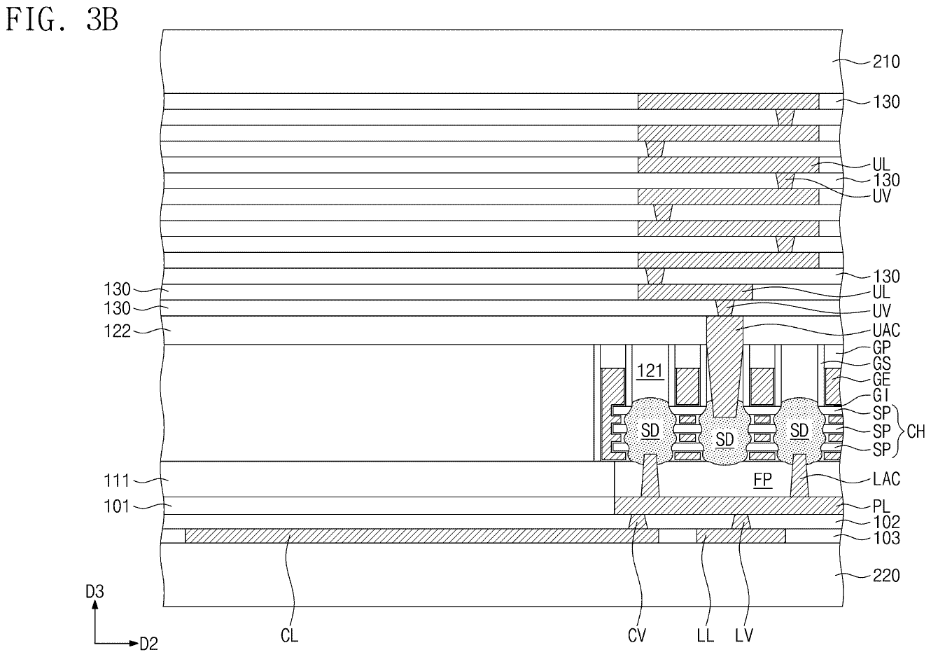

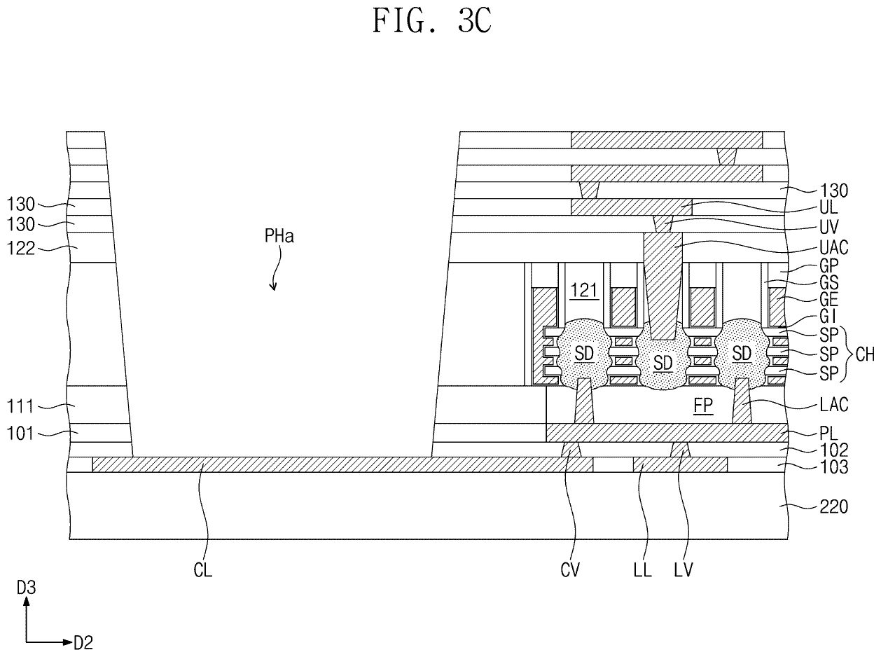

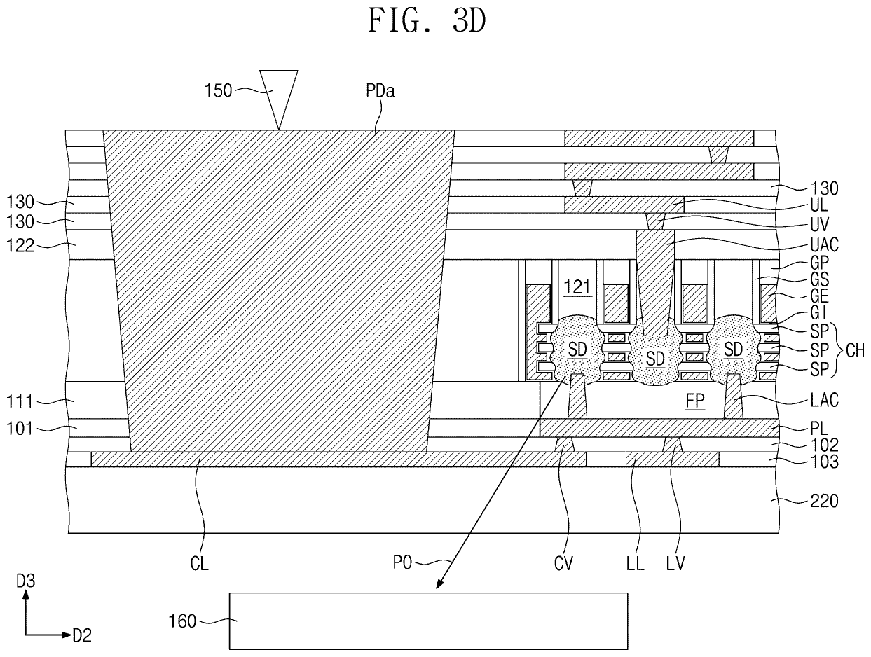

FIGS. 3A, 3B, 3C and 3D are cross-sectional views showing an example method for testing a semiconductor device according to some embodiments.

Referring to FIG. 3A, the fin patterns FP, the element separation layer 111, the channel structures CH, the source/drain patterns SD, the gate insulating layers GI, the gate electrodes GE, the gate capping patterns GP, the gate spacers GS, the first interlayered insulating layer 121, the second interlayered insulating layer 122 and the upper active contacts UAC may be formed.

The upper insulating layers 130 may be formed on the second interlayered insulating layer 122. The upper vias UV and the upper lines UL may be formed in the upper insulating layers 130.

A first substrate 210 may be formed on the upper insulating layers 130. For example, the first substrate 210 may be a silicon substrate. In example embodiments, the first substrate 210 may be formed of a crystalline semiconductor material, such as Si, Ge, or SiGe.

The lower active contacts LAC may be formed. The 101 and the power lines PL may be formed. The second lower insulating layer 102, the lower vias LV and the connection vias CV may be formed. The third lower insulating layer 103, the lower lines LL and the connection lines CL may be formed. The fourth lower insulating layer 104 and the lower vias LV may be formed. The fifth lower insulating layer 105 and the lower pad LP may be formed. The bump BP may be formed.

Referring to FIG. 3B, in example embodiments, the bump BP, the lower pad LP, the lower via LV, the fifth lower insulating layer 105 and the fourth lower insulating layer 104 may be removed. The third lower insulating layer 103, the connection line CL and the lower line LL may be exposed by removing the fourth lower insulating layer 104.

A second substrate 220 may be formed on the third lower insulating layer 103, the connection line CL and the lower line LL. For example, the second substrate 220 may be a silicon substrate.

According to some embodiments, a process of removing the bump BP, the lower pad LP, the lower via LV, the fifth lower insulating layer 105 and the fourth lower insulating layer 104, and a process of forming the second substrate 220, may be performed in a state in which the first substrate 210 is fixed.

Referring to FIG. 3C, the first substrate 210, at least some of the upper insulating layers 130, at least some of the upper lines UL and at least some of the upper vias UV may be removed. For example, the first substrate 210, at least some of the upper insulating layers 130, at least some of the upper lines UL and at least some of the upper vias UV may be removed in a lapping process.

It is illustrated in the figures that a number of the upper insulating layers 130 remaining after the removing process is six, but the number of the upper insulating layers 130 remaining after the removing process is not limited thereto. According to some embodiments, the number of the upper insulating layers 130 remaining after the removing process may be equal to or less than five, or equal to or more than seven.

Penetration holes PHa may be formed. The penetration holes PHa may penetrate the upper insulating layers 130, the second interlayered insulating layer 122, the first interlayered insulating layer 121, the element separation layer 111, the first lower insulating layer 101 and the second lower insulating layer 102 in the third direction D3.

Referring to FIG. 3D, pads PDa may be formed. In examples, a length in the third direction D3 of the pad PDa may be smaller than a width in the second direction D2 of the pad PDa and a width in the first direction D1 of the pad PDa. For example, the length in the third direction D3 of the pad PDa may be about 2.5 μm or 2.2 μm to 2.8 μm, or 2 μm to 3 μm, and a maximum width in the second direction D2 of the pad PDa and a maximum width in the first direction D1 of the pad PDa may be independently about 10 μm, or 9 μm, or 11 μm.

Example semiconductor devices may be tested by using the pad PDa. A voltage may be applied to the pad PDa through the probe pin 150. In examples, the measurement portion 160 may be disposed under the connection line CL. The measurement portion 160 may measure the photon PO generated by the hot electron.

According to some embodiments, a process of removing at least some of the upper insulating layers 130, at least some of the upper lines UL and at least some of the upper vias UV, a process of forming the pads PDa, and a process of testing the semiconductor device may be performed in a state in which the second substrate 220 is fixed.

In example methods for testing the semiconductor device according to some embodiments, the semiconductor device may be tested by using the pad PDa in a state in which lower lines are minimized by removing the lower pad LP and the lower via LV. Accordingly, a phenomenon that the photon PO is blocked by the lower line may be prevented or limited. Accordingly, even when the probe pin 150 is disposed on the semiconductor device, and the measurement portion 160 is disposed under the semiconductor device, defect measurement accuracy of the semiconductor device may be improved.

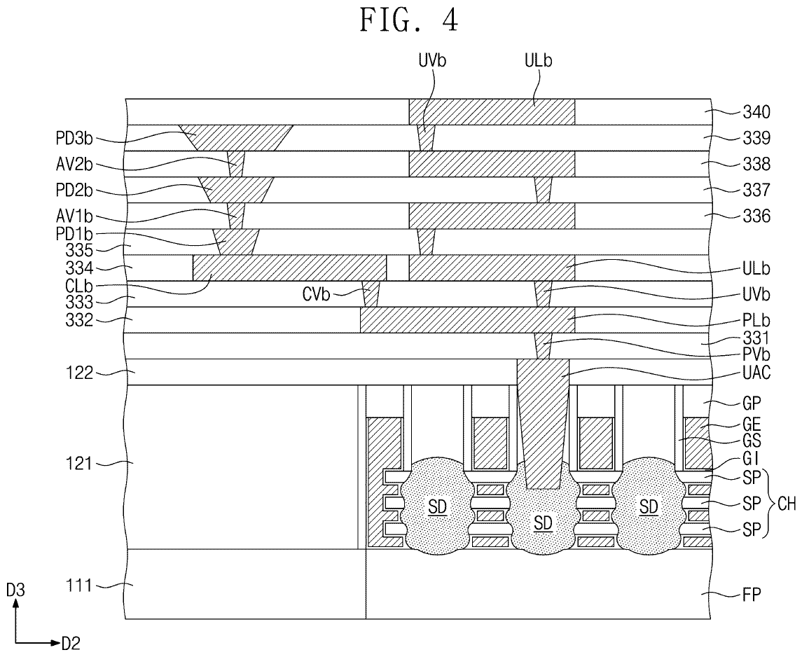

FIG. 4 is a cross-sectional view of a semiconductor device according to some embodiments. Except for what is described herein, the semiconductor device according to FIG. 4 may be the same as the semiconductor device according to FIGS. 1A to 1E.

Referring to FIG. 4, a first upper insulating layer 331, a second upper insulating layer 332, a third upper insulating layer 333, a fourth upper insulating layer 334, a fifth upper insulating layer 335, a sixth upper insulating layer 336, a seventh upper insulating layer 337, an eighth upper insulating layer 338, a ninth upper insulating layer 339 and a tenth upper insulating layer 340 may be sequentially provided on the second interlayered insulating layer 122 along the third direction D3.

A power via PVb may be provided on the upper active contact UAC. The power via PVb may be provided in the first upper insulating layer 331. The power via PVb may include or be a conductive material. A power line PLb may be provided on the power via PVb. The power line PLb may be provided in the second upper insulating layer 332.

A connection via CVb may be provided on the power line PLb. The connection via CVb may be provided in the third upper insulating layer 333. A connection line CLb may be provided on the connection via CVb. The connection line CLb may be provided in the fourth upper insulating layer 334.

A first pad PD1b may be provided on the connection line CLb. The first pad PD1b may be provided in the fifth upper insulating layer 335. A first pad via AV1b may be provided on the first pad PD1b. The first pad via AV1b may be provided in the sixth upper insulating layer 336.

A second pad PD2b may be provided on the first pad via AV1b. The second pad PD2b may be provided in the seventh upper insulating layer 337. A second pad via AV2b may be provided on the second pad PD2b. The second pad via AV2b may be provided in the eighth upper insulating layer 338.

A third pad PD3b may be provided on the second pad via AV2b. The third pad PD3b may be provided in the ninth upper insulating layer 339. The first pad via AV1b and the second pad via AV2b may include or be a conductive material.

Upper vias UVb and upper lines ULb may be provided in the third to tenth upper insulating layers 333 to 340.

In example embodiments, the first pad PD1b may be disposed at a lower level than the second pad PD2b. The second pad PD2b may be disposed at a lower level than the third pad PD3b. A width in the second direction D2 of the first pad PD1b may be smaller than a width in the second direction D2 of the second pad PD2b. The width in the second direction D2 of the second pad PD2b may be smaller than a width in the second direction D2 of the third pad PD3b.

Each of the first to third pads PD1b, PD2b and PD3b may be disposed at the same level as the upper via UVb.

In a process of manufacturing a semiconductor device, the semiconductor device may be tested by using the first to third pads PD1b, PD2b and PD3b. After the fifth upper insulating layer 335 and the first pad PD1b are formed, the semiconductor device may be tested for example, by bringing a probe pin into contact with the first pad PD1b. After the seventh upper insulating layer 337 and the second pad PD2b are formed, the semiconductor device may be tested by bringing a probe pin into contact with the second pad PD2b. After the ninth upper insulating layer 339 and the third pad PD3b are formed, the semiconductor device may be tested by bringing a probe pin into contact with the third pad PD3b.

Because the semiconductor device is tested in example embodiments, by using the first to third pads PD1b, PD2b and PD3b, a defect of the semiconductor device may be found before the process of manufacturing a semiconductor device is completed.

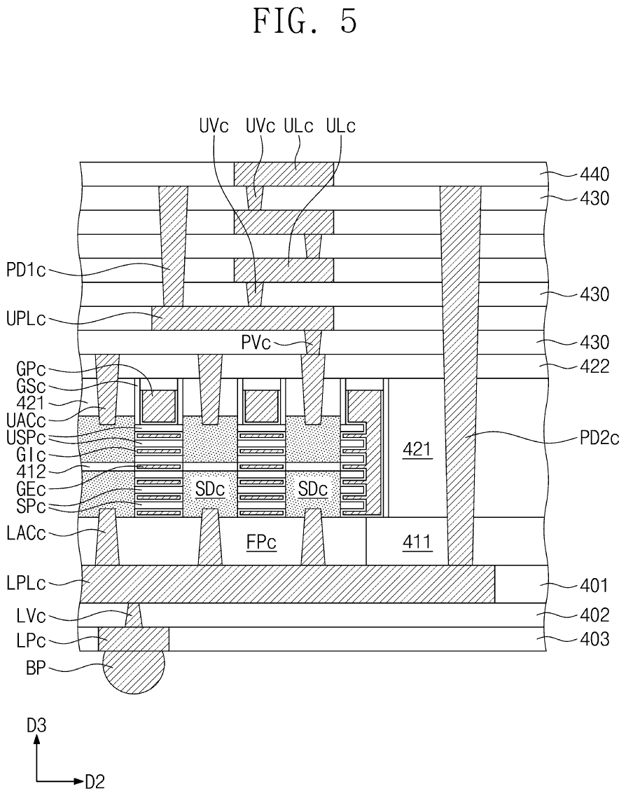

FIG. 5 is a cross-sectional view of the semiconductor device according to some embodiments. Except for what is described herein, the semiconductor device according to FIG. 5 may be to the same as the semiconductor device according to FIGS. 1A to 1E.

Referring to FIG. 5, the semiconductor device may include a fin pattern FPc. The element separation layer 411 surrounding the fin pattern FPc may be provided.

Semiconductor patterns SPc and upper semiconductor patterns USPc overlapping the fin pattern FPc in the third direction D3 may be provided. In examples, the upper semiconductor patterns USPc may be disposed at a higher vertical level than the semiconductor patterns SPc.

Source/drain patterns SDc may be provided on the fin pattern FPc. Upper source/drain patterns USDc overlapping the source/drain patterns SDc in the third direction D3 may be provided. The upper source/drain pattern USDc may be an epitaxial pattern formed in a selective epitaxial growth (SEG) process.

The source/drain pattern SDc may be in contact with the semiconductor pattern SPc. The upper source/drain pattern USDc may be in contact with the upper semiconductor pattern USPc.

Interposed insulating pattern 412 may be provided. The interposed insulating pattern 412 may be disposed the source/drain pattern SDc and the upper source/drain pattern USDc. The interposed insulating pattern 412 may include or be an insulating material.

Gate electrodes GEc may be provided. The gate electrode GEc may surround the semiconductor patterns SPc and the upper semiconductor patterns USPc.

Gate insulating layers GIc may be provided. The semiconductor patterns SPc and the upper semiconductor patterns USPc may be spaced apart from the gate electrode GEc by the gate insulating layer GIc. Gate spacers GSc may be provided on both sides of the gate electrode GEc. A gate capping pattern GPc may be provided on the gate electrode GEc.

A first interlayered insulating layer 421 may be provided. A second interlayered insulating layer 422 may be provided on the first interlayered insulating layer 421.

Upper active contacts UACc may be provided. The upper active contact UACc may be in contact with the upper source/drain patterns USDc. Lower active contacts LACc may be provided. The lower active contact LACc may be in contact with the source/drain pattern SDc.

Upper insulating layers 430 may be provided on the second interlayered insulating layer 422. A power via PVc may be provided on the upper active contact UACc. An upper power line UPLc may be provided on the power via PVc. Upper vias UVc and upper lines ULc electrically connected to the upper power line UPLc may be provided.

A first pad PD1c may be provided on the upper power line UPLc. A lower surface of the first pad PD1c may be in contact with an upper surface of the upper power line UPLc. The first pad PD1c may penetrate some of the upper insulating layers 130 in the third direction D3.

A first lower insulating layer 401 in contact with the element separation layer 411, a second lower insulating layer 402 in contact with the first lower insulating layer 401, and a third lower insulating layer 403 in contact with the second lower insulating layer 402 may be provided.

A lower power line LPLc in contact with the lower active contact LACc may be provided. A second pad PD2c may be provided on the lower power line LPLc. A lower surface of the second pad PD2c may be in contact with an upper surface of the lower power line LPLc.

A cover insulating layer 440 may be provided on the first pad PD1c and the second pad PD2c. In non-limiting examples, all of an upper surface of the first pad PD1c and all of an upper surface of the second pad PD2c may be in contact with the cover insulating layer 440.

A lower via LVc in contact with the lower power line LPLc may be provided. A lower pad LPc in contact with the lower via LVc may be provided. A bump BPc in contact with the lower pad LPc may be provided.

A semiconductor device according to some embodiments may test the semiconductor device by using the first pad PD1c and the upper power line UPLc, and may test the semiconductor device by using the second pad PD2c and the lower power line LPLc.

A semiconductor device according to embodiments of the inventive concept may include a pad electrically connected to a power line disposed at a lower level than source/drain patterns. Accordingly, a voltage may be applied to the power line disposed at the lower level than the source/drain patterns by using a probe pin in contact with the pad, and a hot electron generated by the voltage may be measured.

Although the embodiments of the present application have been described, it is understood that the present invention should not be limited to these embodiments but various changes and modifications can be made by one ordinary skilled in the art within the spirit and scope of the present invention as hereinafter claimed. Therefore, it should be understood that the embodiments described herein are exemplary in all respects and are not intended to be limiting.

What is claimed is:

1. A semiconductor device comprising:
a first source/drain pattern and a second source/drain pattern;
a first power line disposed at a lower level than each of the first source/drain pattern and the second source/drain pattern, the first power line being electrically connected to the first source/drain pattern;
an upper active contact on the second source/drain pattern;
a channel structure connected to at least one of the first source/drain pattern or the second source/drain pattern; and
a first pad electrically connected to the first source/drain pattern through the first power line,
wherein an upper level of an upper surface of the first pad is vertically higher than an upper level of an upper surface of the upper active contact, and
a lower level of a lower surface of the first pad is vertically lower than a lowermost level of the first source/drain pattern and a lowermost level of the second source/drain pattern.

2. The semiconductor device of claim 1, further comprising a cover insulating layer on the first pad,
wherein the upper surface of the first pad is entirely in contact with the cover insulating layer.

3. The semiconductor device of claim 1, further comprising:
a connection via in contact with a lower surface of the first power line; and
a connection line in contact with a lower surface of the connection via,
wherein the lower surface of the first pad is in contact with an upper surface of the connection line.

4. The semiconductor device of claim 3, wherein the lower level of the lower surface of the first pad is vertically lower than the lower surface of the first power line.

5. The semiconductor device of claim 1, further comprising:
a first interlayered insulating layer on the first source/drain pattern and the second source/drain pattern;
a second interlayered insulating layer on the first interlayered insulating layer;
a first upper insulating layer on the second interlayered insulating layer;
a second upper insulating layer on the first upper insulating layer;
an upper via in the first upper insulating layer; and
an upper line in the second upper insulating layer,
wherein the upper active contact penetrates the first and second interlayered insulating layers,
the upper via is in contact with the upper surface of the upper active contact,
the upper line is in contact with an upper surface of the upper via, and
the first pad penetrates the first interlayered insulating layer and the second interlayered insulating layer, and the first upper insulating layer and the second upper insulating layer.

6. The semiconductor device of claim 1, further comprising a second power line spaced apart from the first power line in a first direction, and electrically connected to the first pad.

7. The semiconductor device of claim 1, further comprising:
a third source/drain pattern;
a second power line disposed at a lower vertical level than the third source/drain pattern, and electrically connected to the second source/drain pattern; and
a second pad electrically connected to the third source/drain pattern through the second power line,
wherein the first power line and the second power line are both disposed between the first pad and the second pad.

8. The semiconductor device of claim 1, wherein a distance between the upper surface of the first pad and the lower surface of the first pad is greater than a width of the first pad.

9. A semiconductor device comprising:
a source/drain pattern;
power lines disposed at a lower vertical level than the source/drain pattern;
an upper active contact on the source/drain pattern;
a channel structure connected to the source/drain pattern; and
pads electrically connected to the power lines,
wherein the power lines extend in a first direction,
the power lines are spaced apart from each other in a second direction, and
the pads include:
a first pad and a second pad spaced apart from each other in the first direction with the power lines therebetween; and
a third pad and a fourth pad spaced apart from each other in a second direction intersecting the first direction, with the power lines therebetween.

10. The semiconductor device of claim 9, wherein the power lines comprise:
a first power line electrically connected to the first pad;
a second power line electrically connected to the second pad;
a third power line electrically connected to the third pad; and
a fourth power line electrically connected to the fourth pad,
the semiconductor device further comprising:
a first connection line electrically connecting the first pad and the first power line;
a second connection line electrically connecting the second pad and the second power line;
a third connection line electrically connecting the third pad and the third power line; and
a fourth connection line electrically connecting the fourth pad and the fourth power line,
wherein the first and second connection lines extend in the first direction, and
the third and fourth connection lines extend in the second direction.

11. The semiconductor device of claim 10, wherein the first power line and the second power line are electrically separated from each other,
a power voltage is provided to the first power line and the second power line,
the third power line and the fourth power line are electrically connected to each other, and
a ground voltage is provided to the third power line and the fourth power line.

12. The semiconductor device of claim 9, wherein the power lines comprise a first power line and a second power line that are both electrically connected to the first pad.

13. The semiconductor device of claim 9, wherein the power lines include a first power line electrically connected to the first pad,
further comprising a connection line electrically connecting the first power line and the first pad,
wherein the first pad is disposed at a first sidewall and a second sidewall opposed to the first sidewall of the connection line.

14. The semiconductor device of claim 9, wherein lower surfaces of each of the first to fourth pads are vertically lower than a lowermost portion of the source/drain pattern, and
upper levels of upper surfaces of each of the first to fourth pads are vertically higher than an upper level of an upper surface of the upper active contact.

15. The semiconductor device of claim 9, further comprising a cover insulating layer on the first to fourth pads,
wherein upper surfaces of each corresponding first to fourth pads are entirely in contact with the cover insulating layer.

16. The semiconductor device of claim 9, wherein the power lines include a first power line electrically connected to the first pad,
further comprising:
a connection via in contact with a lower surface of the first power line; and
a connection line in contact with a lower surface of the first connection via,
wherein a width of the connection via increases in a direction approaching the connection line.

17. The semiconductor device of claim 9, wherein when as vertical levels of the first to fourth pads decrease, widths of the first to fourth pads become smaller.

18. A semiconductor device comprising:
a first source/drain pattern and a second source/drain pattern;
semiconductor patterns connected to at least one of the first source/drain pattern or the second source/drain pattern;
a gate electrode overlapping the semiconductor patterns;
a power line disposed at a lower vertical level than the first source/drain pattern and the second source/drain pattern;
an upper active contact on the second source/drain pattern;
a bump disposed at a lower vertical level than the power line, and electrically connected to the power line;
a lower active contact connecting the power line and the first source/drain pattern;
an upper via on the upper active contact;
an upper line on the upper via; and
a pad electrically connected to the first source/drain pattern through the power line and the upper active contact,
wherein a distance between an upper surface of the pad and a lower surface of the pad is greater than a distance between an upper surface of the upper line and an upper surface of the power line.

19. The semiconductor device of claim 18, further comprising a cover insulating layer on the pad,
wherein the upper surface of the pad is entirely in contact with the cover insulating layer.

20. The semiconductor device of claim 18, further comprising:
a connection via in contact with a lower surface of the power line;
a connection line in contact with a lower surface of the connection via; and
a lower insulating layer surrounding the connection via and the pad,
wherein the lower surface of the pad is in contact with an upper surface of the connection line.
